(19) United States
(12) Patent Application Publication
(10) Pub. No.: US 2007/0231746 A1
(43) Pub. Date: Oct. 4, 2007

(54) Treating carbon containing layers in patterning stacks

(76) Inventors: Dimitrios I. Iordanoglou, Louisville, KY (US); Ajay Jain, Milpitas, CA (US); Brad Sun, Portland, OR (US)

Correspondence Address: TROP PRUNER & HU, PC, 1616 S. VOSS ROAD, SUITE 750, HOUSTON, TX, 77057-2631, US

(21) Appl. No.: 11/392,086

(22) Filed: Mar. 29, 2006

(51) Int. Cl. G03F 7/00

(52) U.S. Cl. 430/305; 430/311

(57) ABSTRACT

Adherence between antireflective coating and a carbon containing hard mask may be improved by treating the carbon containing hard mask with a plasma. In some embodiments, using antireflective coatings, such as silicon dioxide, SiOₓH_{y}, SiOₓN_{y}, or organics, adherence to carbon containing hard masks may be improved by exposing the hard masks to a plasma treatment. In some embodiments, the plasma treatment creates a buffer layer with improved adherence to the antireflective coating.

### BACKGROUND

This invention relates generally to the fabrication of integrated circuits and, particularly, to using photoresist to pattern features in semiconductor wafers.

Features may be transferred to a semiconductor wafer in a repeatable fashion using a photolithography system. Radiation exposed to a mask having a particular pattern may then impinge upon a semiconductor substrate. The pattern on the mask may be transferred repeatedly to successive semiconductor substrates. As a result, high volume manufacturing is possible.

The substrate may include a photoresist which may be affected in the regions exposed to the radiation. Those regions may then be relatively harder or easier to remove than unexposed regions.

Underlying the photoresist may be an antireflective coating (ARC). The antireflective coating is used to prevent the radiation from reflecting back through the photoresist again. Such reflections may adversely affect the resolution of the transferred pattern.

Desirable antireflective coatings may include silicon such as SiO₂, SiOₓH_{y}, and SiOₓN_{y} or organic materials.

### BRIEF DESCRIPTION OF THE DRAWINGS

FIG. 1 is an enlarged, cross-sectional view of one embodiment of the present invention at an early stage of manufacture;

FIG. 2 is an enlarged, cross-sectional view corresponding to FIG. 1 at a subsequent stage of manufacture in accordance with one embodiment; and

FIG. 3 is an enlarged, cross-sectional view corresponding to FIG. 2 at a subsequent stage of manufacture according to one embodiment.

### DETAILED DESCRIPTION

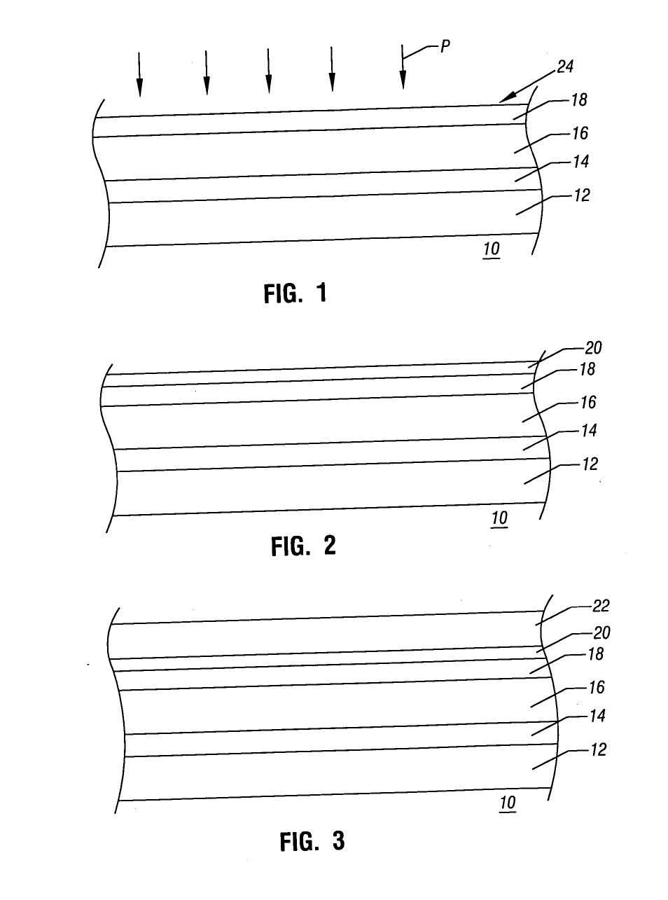

Referring to FIG. 1, a stack may be formed over a substate 10, such as a silicon or germanium substrate. Over the substrate 10 may be a first dielectric layer 12, such as silicon dioxide. A second dielectric layer 14 may or may not be located over the first dielectric layer 12. In one embodiment, the second dielectric layer 14 may be silicon nitride. A third dielectric layer 16 may or may not be positioned over the second dielectric layer 14. The third dielectric layer 16 may be the same material as the first dielectric layer 12 in some embodiments.

Over the dielectric layers 12, 14, and 16, may be positioned a carbon containing hard mask 18. In one embodiment, the mask 18 may include amorphous carbon. However, a variety of other carbon containing layers may be used as well, such as a layer including SiCₓ or SiCₓH_{y}. The mask 18 may, for example, be deposited by the thermal decomposition of a hydrocarbon and an inert gas. Other methods for depositing this carbon containing hard mask may be used, such as plasma decomposition or molecular beam epitaxy.

When it is desired to, thereafter, form certain types of antireflective coatings over the carbon containing hard mask 18, it was appreciated by the present inventors that the adherence of such layers to the carbon containing hard mask 18 may be less than ideal. One result of this weaker adherence is that the layers may tend to delaminate. In the case of lithographic rework, where the resist has to be ashed away and redeposited, the delaminated regions become weak points and tend to further expand and eventually crack. This cracking leaves the carbon containing hard mask exposed to the ensuing etch, resulting in detrimental effects.

For example, antireflective coatings (ARCs) may include silicon dioxide, organic materials, SiOₓ, SiOₓH_{y}, and SiOₓN_{y} (where variables x and y indicate a range of possible deposit ratios, and, in some embodiments, x or y may be from 0.1 to 3 and in some embodiments from 0.1 to 10). All of these materials may be relatively weakly attached to the underlying carbon containing hard mask 18. For example, they may be subject to weak adherence forces of approximately 2 J/m² adherence (using a 4 point bend analysis) which may result in delamination.

As indicated in FIG. 1, in order to improve the adherence to carbon containing material, the carbon containing hard mask 18 may be exposed to a plasma P in the same deposition chamber used to deposit subsequent layers such as an antireflective coating. The plasma treatment may involve a plasma including a mixture of SiH₄, N₂O, and helium gases at a pressure of a few Torr to create a SiOₓN_{y} buffer layer 24. Other plasmas, such as Ar, Ne, N₂, H₂, may also be useful. The plasma exposure may be done in a typical Plasma Enhanced Chemical Vapor Deposition chamber. The exposure may be for a relatively short amount of time. A typical buffer layer 24 may have a thickness of above one monolayer and in other embodiments from five Angstroms up to 30 Angstroms. There may even be cases where the buffer layer can be thicker than 30 Angstroms.

Generally, the carbon containing hard mask 18 reduces resist poisoning. Resist poisoning or footing occurs when amines form on the surface of an antireflective coating. Exposing photoresist may initiate an acidic reaction in the photoresist. The acidic reaction may be neutralized by the amines which are basic. The neutralization may result in leaving undeveloped resist portions. Thus, in some embodiments of the present invention, resist poisoning may be reduced while obtaining good adherence between overlying layers and the carbon containing hard mask 18, thereby reducing defects in some cases.

After treating the carbon containing hard mask 18, an antireflective coating 20 may be deposited from a plasma using SiH₄, CO₂, and He, in one embodiment. As described above, the antireflective coating may contain silicon dioxide, SiOₓH_{y}, SiOₓN_{y}, or organics, all of which may have better adherence to the SiOₓN_{y} buffer layer 24 than to a carbon containing layer. After the antireflective coating 20 has been applied, as shown in FIG. 2, the resist 22 may then be applied as indicated in FIG. 3.

Thereafter, the resist 22 may be patterned using any conventional technique. Etching the patterned resist may proceed using a stack of the layers 22, 20, 18, 16, 14, and 12.

The underlying material, beneath the carbon containing hard mask 18 that is etched, may be any of a variety of materials. The examples given here are intended to be non-limiting.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
treating a carbon containing layer to improve its adherence to an antireflective coating.

2. The method of claim 1 including treating a carbon containing hard mask to improve its adherence to an antireflective coating.

3. The method of claim 1 wherein treating includes exposing the carbon containing layer to a plasma.

4. The method of claim 3 wherein exposing to a plasma includes exposing to a plasma to form a buffer layer.

5. The method of claim 4 including forming a buffer layer that includes silicon.

6. The method of claim 5 including forming a buffer layer that includes nitrogen.

7. The method of claim 6 including forming a buffer layer that includes oxygen.

8. The method of claim 1 including forming an antireflective coating over said treated carbon containing layer.

9. The method of claim 8 including forming an antireflective coating including silicon over said treated carbon containing layer.

10. The method of claim 9 including applying photoresist over said antireflective coating.

11. A semiconductor structure comprising:
a substrate;
a carbon containing layer over said substrate;
an antireflective coating formed on said carbon containing layer; and
a buffer layer between said carbon containing layer and said antireflective coating.

12. The structure of claim 11 wherein said buffer layer includes silicon.

13. The structure of claim 12 wherein said buffer layer includes nitrogen.

14. The structure of claim 13 wherein said buffer layer includes oxygen.

15. The structure of claim 11 wherein said buffer layer includes SiOₓN_{y}

16. The structure of claim 11 wherein said carbon containing layer is a carbon hard mask.

17. The structure of claim 16 wherein said carbon containing hard mask includes amorphous carbon.

18. The structure of claim 11 including a photoresist over said antireflective coating.

19. The structure of claim 11 wherein said antireflective coating includes silicon.

20. The structure of claim 11 wherein said antireflective coating includes organic material.
